(19) United States
(12) Patent Application Publication
(10) Pub. No.: US 2008/0238526 A1
(43) Pub. Date: Oct. 2, 2008

(54) Fast Switching Circuit With Input Hysteresis

(75) Inventor: Milen Penev, Dietikon (CH)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/574,975

(22) PCT Filed: Aug. 11, 2005
(86) PCT No.: PCT/IB2005/052671

§ 371 Date: Feb. 1, 2008

(30) Foreign Application Priority Data
Sep. 8, 2004 (EP) 04104315.9

(51) Int. Cl. H03K 17/16

(52) U.S. Cl. 327/389

(57) ABSTRACT

The present invention relates to a switching circuit and a method of controlling a threshold voltage of a semiconductor switching element of the switching circuit, wherein a bulk voltage of the semiconductor switching element (Mᵢ) is selected in response to a control signal derived from an output signal of the semiconductor switching element (Mᵢ). Thereby, a fast switching circuit with hysteresis, smaller cross current and precisely adjustable threshold voltages can be provided.

The present invention relates to a switching circuit having an input hysteresis based on a modulation of a threshold voltage of at least one semiconductor switching element, and to a method of controlling a threshold voltage of such a semiconductor switching element.

In digital circuits, there are sometimes cases where an input signal doesn't directly fit to the processing requirements for digital signals. For various reasons it may have slow rise and/or fall times, or may have acquired some noise that could be sensed by further circuitry. It may even be an analog signal whose frequency is to be measured. All of these conditions, and many others, require a specialized circuit that will “clean up” the signal and force it to true digital shape.

In particular, integrated circuits are sometimes operated in very difficult conditions, such as noisy environments, and have to process week and unstable signals. To improve the noise sensibility of the circuits, especially at their input parts, a lot of design techniques have been used. A common approach is to implement some input hysteresis. Hysteresis is the difference between input signal levels at which switching circuits, such as comparators, turn off and turn on. A small amount of hysteresis can be useful because it reduces the circuit sensitivity to noise, and helps reducing multiple transitions at the output when changing the state. Normally, in a discrete design, an external discrete resistor is added between the comparators' output and a positive input, creating a week positive feedback loop. When the output makes a transition, the positive feedback slightly changes the positive input so as to reinforce the output change.

A popular switching circuit with input hysteresis is the so called Schmidt Trigger. However, a Schmidt Trigger circuit has the disadvantages of being relatively slow, of having high cross currents, i.e. direct DC currents flowing from the supply voltage V_{dd} through internal transistors directly to ground and not via the load, and of having threshold voltages which depend on the power supply range, which are defined by the design and technology parameters of the transistors and thus cannot be changed to adjust the input hysteresis.

It is therefore an object of the present invention to provide a fast switching circuit with input hysteresis and small cross currents, which allows individual adjustment of the threshold voltages.

This object is achieved by a switching circuit as claimed in claim 1 and by a control method as claimed in claim 9.

Accordingly, a predetermined voltage applied to a bulk terminal of the semiconductor switching element is selected by selecting means based on the output signal of the switching element. An input hysteresis can thus be provided based on a modulation of the threshold voltage in response to the output voltage of the semiconductor switching element without the disadvantages of the Schmidt Trigger circuit, since at least one of the predetermined voltages can be changed to precisely adjust the threshold voltages without dependency on the spread of the technology parameters. Moreover, a fast switching behaviour can be achieved as a result of the back gate effect based on which the threshold voltage is changed in response to a change of the bulk voltage. The resultant faster switching behaviour leads to reduced cross currents in comparison to the slower switching Schmidt Trigger circuit.

The at least one control signal may be obtained from an output of at least one inverter circuit connected to the output of the semiconductor switching element. By obtaining the at least one control signal from the output of an inverter circuit, a predetermined binary value of the control signal can be defined based on which the connection of the selected predetermined voltage to the bulk terminal can be controlled. In particular, a fast control signal may be obtained from an output of the first inverter circuit following the output of the semiconductor switching element, and a second control signal may be obtained from an output of a second inverter circuit connected to the output of the first inverter circuit. This ensures that the first and second control signals have opposite states and can be used to switch one of two predetermined voltages to the bulk terminal. As a specific example, the switching circuit may comprise four inverter circuits, wherein the semiconductor switching element belongs to an input inverter circuit, the first inverter circuit corresponds to the second last inverter circuit and the second inverter circuit corresponds to the last inverter circuit. This configuration improves the switching behaviour, as detrimental effects by the so-called rail-to-rail swing at the gates of the switching elements of the inverter circuits can be alleviated. A rail-to-rail swing describes a swinging behavior between supply rails allowed in circuits with lower supply voltages to improve the performance at small signals and minimize distortion by creating more signal “head room”.

The selecting means may comprise at least one semiconductor switching element having a control terminal to which the at least one control signal is applied. Thereby, the whole circuit can be arranged as an integrated circuit consisting of semiconductor switching elements, such as, for example metal oxide semiconductor (NOS) transistors or other controllable and/or active semiconductor switching elements. As an example for this specific aspect, a first predetermined voltage may be supplied to the bulk terminal of the semiconductor switching element via a first semiconductor switching element, and a second predetermined voltage may be supplied to the bulk terminal via a second semiconductor switching element, wherein the first semiconductor switching element is controlled by a first control signal and the second semiconductor switching element is controlled by a second control signal which is inversely related to the first control signal. Thereby, the connection to the required predetermined voltage which defines the threshold is controlled by control signal with opposite states which may thus easily be generated at successive outputs of two inverter circuits, so that a simple configuration of the switching circuit can be achieved.

The present invention will now be described on the basis of a preferred embodiment with reference to the accompanying drawings, in which:

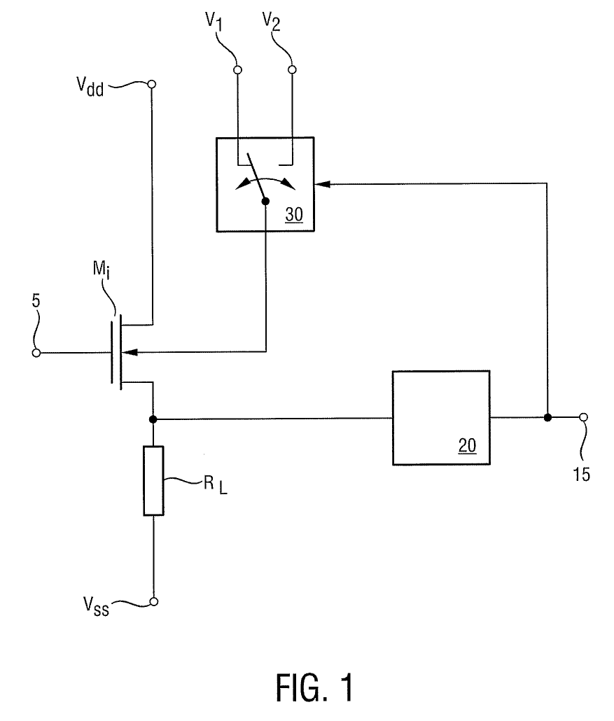

FIG. 1 shows a schematic block diagram of a switching circuit according to the preferred embodiment; and

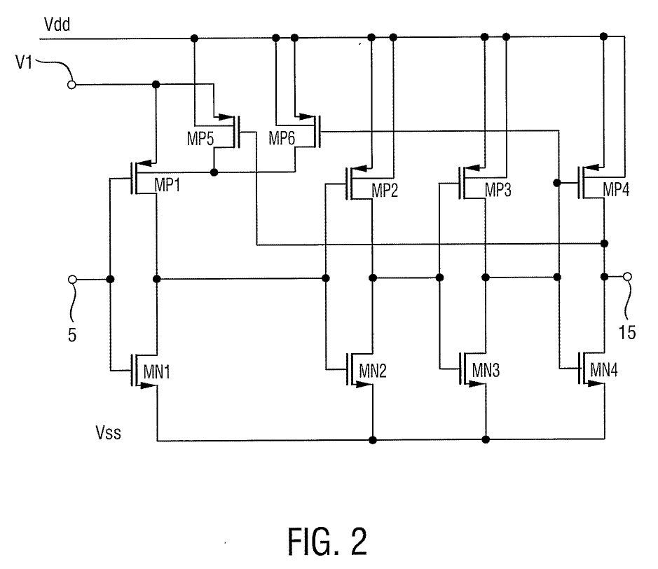

FIG. 2 shows a schematic circuit diagram of an integrated switching circuit according to an example of a specific implementation of the preferred embodiment.

The preferred embodiment will now be described on the basis of an input buffer for integrated circuits.

The operating principle of the proposed input buffer with hysteresis is based on the modulation of a threshold of a semiconductor switching element, such as a MOS transistor, as a function of the bulk voltage. The bulk voltage is a voltage applied to the substrate of the semiconductor switching element via a bulk or substrate terminal.

The effect of the bulk voltage on the threshold voltage is known as the so-called back gate effect. It can be described by the following equation:

Vₜₕ=Vₜₕ₀+γ·(\sqrt{|−2F_{f}+V_{sb}|}−\sqrt{|−2F_{f}|})

where Vₜₕ denotes the actual threshold voltage, V_{sb} denotes the bulk voltage used for controlling the threshold voltage, Vₜₕ₀ denotes the threshold voltage at V_{sb}=0, γ denotes the body factor, body-effect coefficient or bulk threshold parameter, and F_{f} denotes the equilibrium electrostatic (Fermi) potential.

Hence, a predefined relationship between the threshold voltage of the semiconductor switching element and the applied bulk voltage is given and can be used for controlling the hysteresis of the input buffer circuit.

FIG. 1 shows a schematic block diagram of a buffer or switching circuit according to the preferred embodiment.

In particular, a semiconductor switching element with a bulk terminal, such as a MOS transistor Mᵢ, is provided at the input of the switching circuit, wherein an input terminal 5 is connected to the gate of the MOS transistor Mᵢ. The drain terminal of the MOS transistor Mᵢ is connected to a supply voltage V_{dd}, and the source terminal of the MOS transistor Mᵢ is connected via a load resistor which may represent any input resistor or impedance of other semiconductor elements or circuits through which the cross current flows to a second supply voltage Vₛₛ or a ground terminal. In the present example, a processing circuit 20 which may be any digital processing circuit and which may comprise at least one inverter circuit is connected to the source terminal of the MOS transistor Mᵢ. The output signal of the processing circuit 20 is supplied to an output terminal 15 and is also used as a control signal for controlling a selection or switching circuit 30 which connects the bulk terminal of the MOS transistor Mᵢ to one of two predetermined voltages V₁ and V₂. The selection circuit 30 may be implemented by any switching element or switching circuit which can be used for selectively connecting one of the predetermined voltages V₁ and V₂ to the bulk terminal of the MOS transistor Mᵢ.

According to FIG. 1, a modulation of the threshold voltage of the MOS transistor Mᵢ at the input of the switching circuit can be achieved by selectively changing the bulk voltage between predetermined values in response to a control signal derived from the output of the switching circuit. Thereby, an input hysteresis can be established similar to a Schmidt Trigger circuit, while the predetermined voltages V₁ and V₂ can be exactly adjusted and the switching speed can be improved especially if the circuit components are implemented in an integrated circuit.

FIG. 2 shows a specific implementation of the general block diagram of FIG. 1 as an integrated buffer circuit which includes four inverter circuits consisting of respective NMOS transistors and PMOS transistors MN1 and MP1, MN2 and MP2, MN3 and MP3, MN4 and MP4, wherein the PMOS transistor MP1 of the first inverter stage is used as the controlled semiconductor switch which defines an input hysteresis with controlled threshold values. In the present example, the predetermined voltage V₂ of FIG. 1 corresponds to the supply voltage V_{dd} of the controlled PMOS transistor MP1. The selection circuit 30 of FIG. 1 is implemented by two additional PMOS transistors MP5 and MP6 which gate terminals are connected to the outputs of the second last and last inverter circuits, respectively. Thereby, it is assured that the control signals supplied to the gates of the two selecting transistors MP5 and MP6 have opposite logical states, so that one of the selecting transistors MP5 and MP6 is switched off and is thus set to an open state and the other is switched on and is thus set to a closed state.

In particular, the first selecting transistor MP5 connects the dedicated predetermined voltage V₁ to the controlled PMOS transistor MP1, while the second selecting transistor MP6 connects the supply voltage V_{dd} to the controlled PMOS transistor MP1.

In the present example, it is to be noted that the controlled PMOS transistor MP1 is connected to the dedicated predetermined voltage V₁ instead of the supply voltage V_{dd}, while the dedicated predetermined voltage V₁ is preferably smaller than the supply voltage V_{dd} and is generated inside the chip or applied from an external circuit. As already mentioned, the selecting transistors MP5 and MP6 act as switches and connect the bulk terminal of the controlled transistor MP1 either to the dedicated predetermined voltage V₁ or to the supply voltage V_{dd}. In this way, the threshold voltage of the controlled transistor MP1 can be changed in response to the control signals supplied to the gates of the selecting transistors MP5 and MP6. A change of the threshold voltage of the controlled transistor MP1 causes a change of the threshold voltage of the whole inverter circuit consisting of the transistors MP1 and MN1 and adds an input hysteresis to the whole input buffer circuit.

The input buffer circuit of FIG. 2 functions as follows. At a high input value at the input terminal 5, the output value of the fourth inverter stage at the output terminal 15 is at a high logical level and the output value of the third inverter stage is at a low logical value. This causes the second selecting transistor MP6 to switch off, while the first selecting transistor MP5 is switched on and connects the dedicated predetermined voltage V₁ to the bulk terminal of the controlled transistor MP1. Thus, the selection circuit 30 which functions as a bulk voltage controller selects the dedicated predetermined voltage V₁ as the bulk voltage. In this case, the threshold is relatively low. Similarly, if the input signal at the input terminal 5 is at high input value, the output of the fourth inverter stage is at a low logical level and the output of the third inverter stage is at a high logical level, which causes the second selecting transistor MP6 to switch on and connect the supply voltage V_{dd} to the bulk terminal. In this case, the input buffer has a high threshold.

Thus, a new type of input buffer is proposed which comprises a bulk voltage controller or selection circuit to control the bulk voltage of a first inverter stage. The bulk voltage controller may select either one of the supply voltages V_{dd}, V_{SS} or any voltage value between Vₛₛ and V_{dd} as the bulk voltage of the first inventor stage. Furthermore, the bulk voltage controller or selection circuit has at least one control input coupled to an output of one of the inverter stages.

The proposed input buffer circuit can be used in any type of integrated circuit where some input hysteresis is required. The predetermined voltages to be selectively connected to the bulk terminal may be generated inside the integrated circuit or may be supplied from an external circuit. As already mentioned in connection with FIG. 1, any selection circuitry can be used to control the bulk voltage, and the selection circuit is not restricted to the implementation with the first and second selecting transistors MP5 and MP6.

Furthermore, a buffer circuit with only two inverter stages may be used, wherein the feedback control terminal of the second selecting transistor MP6 is connected to the output of the first inverter stage and the feedback control terminal of the first selecting transistor MP5 is connected to the second inverter stage.

Furthermore, if NMOS isolated transistors are used instead of normal NMOS transistors at least in the first inverter stage, the same bulk control may also be applied at the NMOS transistor MN1 in which case two well technologies must be applied, which requires an additional reference or predetermined voltage. To control the bulk voltage of the NMOS transistor MN1, it has to be placed into a separate p-well. High voltage technologies offer this kind of devices. Using this type of circuitry, the first inverter stage can be made symmetrical and selection switches for the bulk voltages of both the PMOS transistor MP1 and the NMOS transistor MN1 can be provided. Thereby, threshold voltage regulation or control can be made more flexible at the expense of an additional voltage source, similar to the dedicated predetermined voltage V₁, for the controlled NMOS transistor MN1.

It is noted that the described drawing figures are only schematic and are not limiting. In the drawings, the size of some of the elements may be exaggerated and not drawn on scale for illustrative purposes. Where the term “comprising” is used in the present description and claims it does not exclude other elements or steps. Where an indefinite or definite article is used when referring to a singular noun, e.g. “a” or “an”, “the” this includes a plurality of that noun unless something else is specifically stated. The terms first, second, third and the like in the description and in the claims are used for distinguishing between similar elements and not necessarily for describing a sequential or chronological order. It is to be understood that the embodiments of the invention described herein are capable of operating in other sequences than described or illustrated herein. Moreover, although preferred embodiments, specific constructions and configurations have been discussed herein, various changes or modifications in form and detail may be made without departing from the scope of the attached claims.

1. A switching circuit having an input hysteresis based on a modulation of a threshold voltage of at least one semiconductor switching element, said switching circuit comprising selecting means for selecting one of at least two predetermined voltages in response to at least one control signal derived from an output signal of said semiconductor switching element, and for applying said selected predetermined voltage to a bulk terminal of said semiconductor switching element.

2. A switching circuit according to claim 1, wherein said at least one control signal is obtained from an output of at least one inverter circuit connected to the output of said semiconductor switching element.

3. A switching circuit according to claim 2, wherein a first control signal is obtained from an output of a first inverter circuit following the output of said semiconductor switching element and a second control signal is obtained from an output of a second inverter circuit connected to the output of said first inverter circuit.

4. A switching circuit according to claim 3, wherein said switching circuit comprises four inverter circuits wherein said semiconductor switching element belongs to an input inverter circuit, said first inverter circuit corresponds to the second last inverter circuit and said second inverter circuit corresponds to the last inverter circuit.

5. A switching circuit according to claim 1, wherein said selecting means comprises at least one semiconductor switching element (MP5, MP6) having a control terminal to which said at least one control signal is applied.

6. A switching circuit according to claim 5, wherein a first predetermined voltage is supplied to said bulk terminal of said semiconductor switching element via a first semiconductor switching element and a second predetermined voltage is supplied to said bulk terminal via a second semiconductor switching element, said first semiconductor switching element being controlled by a first control signal and said second semiconductor switching element being controlled by a second control signal which is inversely related to said first control signal.

7. A switching circuit according to claim 1, wherein said semiconductor switching element is an MOS transistor.

8. A switching circuit according to claim 1, wherein said switching circuit is an integrated buffer circuit.

9. A method of controlling a threshold voltage of a semiconductor switching element to provide a fast switching circuit with input hysteresis, said method comprising the step of selecting a bulk voltage of said semiconductor switching element in response to a control signal derived from an output signal of said semiconductor switching element.
